(19) United States
(12) Patent Application Publication
(10) Pub. No.: US 2025/0098089 A1
(43) Pub. Date: Mar. 20, 2025

(54) DISPLAY DEVICE, APPARATUS FOR MANUFACTURING THE DISPLAY DEVICE, AND METHOD OF MANUFACTURING THE DISPLAY DEVICE

(71) Applicant: SAMSUNG DISPLAY CO., LTD., YONGIN-SI (KR)

(72) Inventors: Kyung Hoon CHAE, Yongin-si (KR); Moon Kon KIM, Yongin-si (KR); Hee Chang KIM, Yongin-si (KR); Ki Yol NAM, Yongin-si (KR); Min Hee PARK, Yongin-si (KR); Ha Young CHOI, Yongin-si (KR)

(21) Appl. No.: 18/657,855

(22) Filed: May 8, 2024

(30) Foreign Application Priority Data
Sep. 15, 2023 (KR) 10-2023-0122889

(51) Int. Cl. H05K 5/03; G04G 17/04

(52) U.S. Cl. CPC H05K 5/03; G04G 17/045

(57) ABSTRACT

A display device including: a display driving module including a display panel; a cover window including a central portion overlapping the display driving module and a curved portion surrounding the display driving module; and an outer structure disposed between the display driving module and the curved portion and surrounding the display driving module, wherein the outer structure is spaced apart from the display driving module.

This application claims priority under 35 U.S.C. § 119 to Korean Patent Application No. 10-2023-0122889, filed on Sep. 15, 2023, in the Korean Intellectual Property Office, the disclosure of which is incorporated by reference herein in its entirety.

### 1. TECHNICAL FIELD

The present disclosure relates to a display device, an apparatus for manufacturing the display device, and a method of manufacturing the display device.

### 2. DESCRIPTION OF THE RELATED ART

As the information society progresses, the demand for display devices capable of displaying images is growing in various forms. These display devices may include flat panel displays, such as liquid crystal displays, field emission displays, and light emitting displays. The category of light emitting displays includes organic light emitting display devices, which utilize organic light emitting diode elements for light emission, and light emitting diode display devices that employ inorganic light emitting diode elements for light emission.

Flexible display devices, designed with edge portions that bend to achieve a predetermined curvature for enhanced aesthetics, have been introduced. Consequently, there is active research focused on cover windows that include curved surfaces.

As technology advances, the cost and complexity of manufacturing display devices increases. In response, a process of modularizing each component of the display device and assembling them individually is being actively used.

### SUMMARY

Embodiments of the present disclosure provide a display device which minimizes dead space between a display driving module and a cover window.

Embodiments of the present disclosure provide a display device that minimizes damage caused by the pressing of a display driving module, an apparatus for manufacturing the display device, and a method of manufacturing the display device.

Embodiments of the present disclosure provide an apparatus for manufacturing a display device and a method of manufacturing the display device with improved process efficiency.

According to an embodiment of the present disclosure, there is provided a display device including: a display driving module including a display panel; a cover window including a central portion overlapping the display driving module and a curved portion surrounding the display driving module; and an outer structure disposed between the display driving module and the curved portion and surrounding the display driving module, wherein the outer structure is spaced apart from the display driving module.

The outer structure directly contacts the curved portion.

The outer structure is disposed away from an outer edge of the display driving module.

The outer structure does not directly contact the display driving module.

A lower surface of the outer structure is located on the same plane as a lower surface of the curved portion.

The outer structure includes a first portion contacting an inner surface of the curved portion and a second portion overlapped by a lower surface of the first portion.

The second portion overlaps the first portion and the curved portion in a thickness direction of the display device.

The second portion contacts the lower surface of the curved portion.

An outermost surface of the curved portion protrudes beyond an outer surface of the second portion adjacent thereto.

The display device further includes a middle frame located opposite the cover window with the second portion of the outer structure interposed therebetween, wherein the outer surface of the second portion is covered by the cover window or the middle frame.

The display device further includes a first coupling member disposed between the cover window and the middle frame, wherein the middle frame includes a middle sidewall facing the curved portion of the cover window, and the first coupling member contacts a lower surface of the second portion, the lower surface of the curved portion, and an upper surface of the middle sidewall.

The first coupling member includes a first coupling portion contacting the second portion, a second coupling portion contacting the curved portion, and a step portion between the first coupling portion and the second coupling portion.

The lower surface of the outer structure is higher than the lower surface of the curved portion.

The display device further includes a middle frame located below the cover window, wherein the middle frame includes a step portion overlapping the cover window in a horizontal direction.

An upper surface of the step portion is higher than the lower surface of the curved portion.

The display device further includes a first coupling member disposed between the cover window and the middle frame, wherein the first coupling member includes a first coupling portion disposed on the step portion and a second coupling portion disposed on the lower surface of the curved portion.

The display driving module further includes a driving chip and a driving board disposed on an end of the display panel.

According to an embodiment of the present disclosure, there is provided a display device including: a display driving module including a display panel; a cover window including a central portion overlapping the display driving module and a curved portion surrounding the display driving module; and an outer structure disposed between the display driving module and the curved portion and surrounding the display driving module, wherein the outer structure overlaps the display driving module in a thickness direction of the display panel.

The outer structure directly contacts the display driving module.

The display panel includes a main area, a bending area disposed on a first side of the main area and a sub-area disposed on a second side of the bending area, and the outer structure includes a first portion disposed outside the bending area and a second portion disposed inside the bending area.

The outer structure further includes a third portion covering the sub-area of the display panel.

The outer structure includes a fourth portion disposed on a lower surface of the third portion, and the fourth portion has a step shape.

According to an embodiment of the present disclosure, there is provided an apparatus for manufacturing a display device, the apparatus including: an upper mold and a lower mold facing each other; and an inner mold located between the upper mold and the lower mold, wherein the inner mold includes: outer walls; inner walls located inside the outer walls; a cavity disposed between the outer walls and the inner walls; an accommodating portion disposed inside the inner walls; and an inlet and an outlet open to the cavity.

The apparatus is configured to manufacture the display device including a display driving module and a cover window, wherein lower surfaces of the inner walls are located on the cover window.

According to an embodiment of the present disclosure, there is provided a method of manufacturing a display device which includes a display driving module and a cover window, the method including: coupling a mold unit and the display device together; injecting paste through an inlet of the mold unit; and forming an outer structure by curing the paste, wherein the outer structure is disposed between the display driving module and the cover window.

The method further including removing a tip formed on the outer structure.

### BRIEF DESCRIPTION OF THE DRAWINGS

The above and/or other features of the present disclosure will become more apparent from the following description of the embodiments of the present disclosure, taken in conjunction with the accompanying drawings in which:

FIG. 1 is a perspective view of a display device according to an embodiment;

FIG. 2 is a front view illustrating an unfolded state of a display driving module according to an embodiment;

FIG. 3 is a rear view illustrating the unfolded state of the display driving module according to the embodiment;

FIG. 4 is a rear view illustrating a bent state of the display driving module according to the embodiment;

FIG. 5 is a schematic side view illustrating the bent state of the display driving module according to the embodiment;

FIG. 6 is a schematic cross-sectional view illustrating a stacked structure of a display module according to an embodiment;

FIG. 7 is a schematic cross-sectional view of a main body unit according to an embodiment;

FIG. 8 is an enlarged view of area A of FIG. 7;

FIG. 9 is a schematic rear view of the main body unit according to the embodiment of FIG. 7;

FIG. 10 is a schematic cross-sectional view of a main body unit according to an embodiment;

FIG. 11 is an enlarged view of area B of FIG. 8;

FIG. 12 is a schematic cross-sectional view of a main body unit according to an embodiment;

FIG. 13 is an enlarged view of area C of FIG. 12;

FIG. 14 is a schematic rear view of the main body unit according to the embodiment of FIG. 12;

FIG. 15 is a schematic cross-sectional view of a main body unit according to an embodiment;

FIG. 16 is an enlarged view of area D of FIG. 15;

FIG. 17 is a schematic cross-sectional view of a main body unit according to an embodiment;

FIG. 18 is an enlarged view of area E of FIG. 17;

FIG. 19 is a schematic cross-sectional view of a main body unit according to an embodiment;

FIG. 20 is an enlarged view of area F of FIG. 19;

FIG. 21 is a schematic cross-sectional view of a main body unit according to an embodiment;

FIG. 22 is an enlarged view of area G of FIG. 21;

FIG. 23 is a flowchart illustrating a method of manufacturing a display device according to an embodiment;

FIG. 24 is a perspective view illustrating operation S100 of FIG. 23;

FIG. 25 is a cross-sectional view illustrating operation S100 of FIG. 23;

FIG. 26 is a cross-sectional view illustrating operation S200 of FIG. 23;

FIG. 27 is an enlarged view of area H of FIG. 26;

FIG. 28 is a cross-sectional view illustrating operation S300 of FIG. 23;

FIG. 29 is a cross-sectional view illustrating operation S400 of FIG. 23;

FIG. 30 is a cross-sectional view illustrating operation S500 of FIG. 23; and

FIG. 31 is a cross-sectional view illustrating operation S600 of FIG. 23.

### DETAILED DESCRIPTION OF THE EMBODIMENTS

The present disclosure will now be described more fully hereinafter with reference to the accompanying drawings, in which embodiments of the present disclosure are shown. This disclosure may, however, be embodied in different forms and should not be construed as limited to the embodiments set forth herein.

It will be understood that when a layer is referred to as being “on” another layer or substrate, it can be directly on the other layer or substrate, or intervening layers may be present. The same reference numbers may indicate the same components throughout the specification.

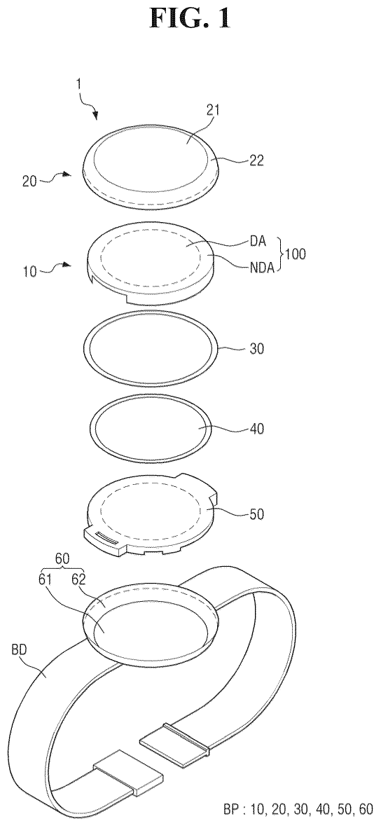

FIG. 1 is a perspective view of a display device 1 according to an embodiment.

Referring to FIG. 1, the display device 1 according to the embodiment may include a main body unit BP and a wearable portion BD. Although a smart watch is illustrated as an example of the display device 1 in the present specification, the present disclosure is not limited thereto. In an embodiment, the display device 1 may also be various display devices 1 such as a smartphone, a television, and a computer.

The main body unit BP may include a display driving module 10 on which an image is displayed, a cover window 20, an outer structure 30, a coupling member 40, a middle frame 50, and a bottom cover 60. In the main body unit BP, the bottom cover 60, the middle frame 50, the coupling member 40, the outer structure 30, the display driving module 10, and the cover window 20 may be sequentially arranged.

The display driving module 10 may include a display panel 100. The display panel 100 may be a screen on which a variety of information, content, user interfaces, and more are displayed as images. The display panel 100 may be, but is not limited to, an organic light emitting display panel or a liquid crystal display panel. The display panel 100 may include a display area DA where an image is displayed and a non-display area NDA located around the display area DA. As illustrated in FIG. 1, the display panel 100 may be circular in a plan view. However, the present disclosure is not limited thereto, and the display panel 100 may also have various shapes, for example, the display panel 100 may have a polygonal shape, such as a quadrilateral, or an oval shape.

The cover window 20 may be disposed on the display driving module 10 to protect the display driving module 10. The cover window 20 may transmit light emitted from the display driving module 10. In some embodiments, the cover window 20 may include a light blocking portion to block some of the light emitted from the display driving module 10.

The cover window 20 may be made of a transparent plastic material, a glass material, or a tempered glass material. In an embodiment, the cover window 20 may be made of any one of sapphire glass and gorilla glass or may have a stacked structure thereof. In an embodiment, the cover window 20 may include any one of polyethyleneterephthalate (PET), polycarbonate (PC), polyethersulfone (PES), polyethylenapthanate (PEN), and polynorborneen (PNB). The cover window 20 may be made of tempered glass in consideration of scratch resistance and transparency.

The cover window 20 may overlap the display driving module 10 and cover a front surface of the display driving module 10. The cover window 20 may have a shape similar to the shape of the display driving module 10 in a plan view. However, the cover window 20 may be larger in size than the display driving module 10. For example, the cover window 20 may protrude further outward than the display driving module 10. The planar shape of the cover window 20 may be the same as the planar shape of the main body unit BP. For example, the cover window 20 may be circular in a plan view. However, the present disclosure is not limited thereto, and the cover window 20 may also have various shapes, for example, the cover window 20 may have a polygonal shape, such as a quadrilateral, or an oval shape.

The cover window 20 may include a central portion 21 and a curved portion 22.

The central portion 21 may be located in the center of the cover window 20 and may be generally flat. In an embodiment, the central portion 21 may be an area corresponding to the display area DA of the display driving module 10. For example, the central portion 21 may overlap the display area DA of the display driving module 10. The central portion 21 of the cover window 20 may cover the entire display area DA of the display driving module 10. However, the present disclosure is not limited thereto, and the central portion 21 of the cover window 20 may also cover only a part of the display area DA of the display driving module 10.

The curved portion 22 may be disposed around the central portion 21. The curved portion 22 may surround the central portion 21. The curved portion 22 may be a portion bent from the central portion 21. For example, the curved portion 22 may be integrally formed with the central portion 21. The curved portion 22 may be bent from an edge of the central portion 21. In some embodiments, a first portion of the curved portion 22 may include a curved surface having a predetermined curvature, and a second portion of the curved portion 22 may be flat. The degree (or angle) by which the curved portion 22 is bent from the central portion 21 may be an obtuse angle. However, the present disclosure is not limited thereto, and the degree (or angle) by which the curved portion 22 is bent from the central portion 21 may also be a right angle or an acute angle.

In an embodiment, the curved portion 22 may include a curved surface having a predetermined curvature. The curvature of the curved portion 22 may be constant in each area of the curved portion 22. However, the present disclosure is not limited thereto, and the curvature of the curved portion 22 may also be different in each area of the curved portion 22. For example, the curved portion 22 may have a curved shape and may be inclined at a first angle, for example, 120 degrees from the central portion 21. The first angle is an angle formed between an inner surface of the central portion 21 and an inner surface of the curved portion 22. Accordingly, the curved portion 22 curved from the central portion 21 may be expressed as a three-dimensional window or a three-dimensional sidewall window.

The outer structure 30 may be disposed between the cover window 20 and the middle frame 50. The outer structure 30 may couple the display driving module 10, the cover window 20, and the coupling member 40 (or the middle frame 50) together.

The outer structure 30 may be disposed along an edge of the display driving module 10. In some embodiments, the outer structure 30 may have a ring shape with a central hole in a plan view. For example, the outer structure 30 may have a donut shape or a ring shape in a plan view. In a plan view, the shape and size of the outer structure 30 may correspond to the shape and size of an inner surface of the cover window 20. For example, when the inner surface of the cover window 20 has a circular shape in a plan view, the outer structure 30 may also have a circular shape.

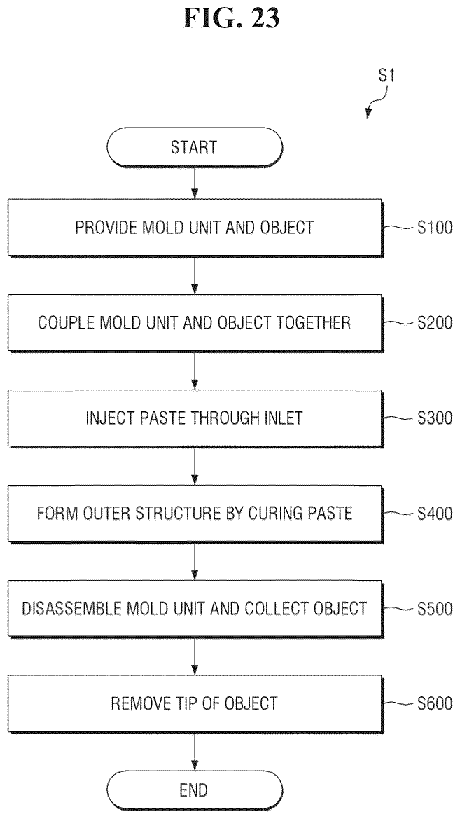

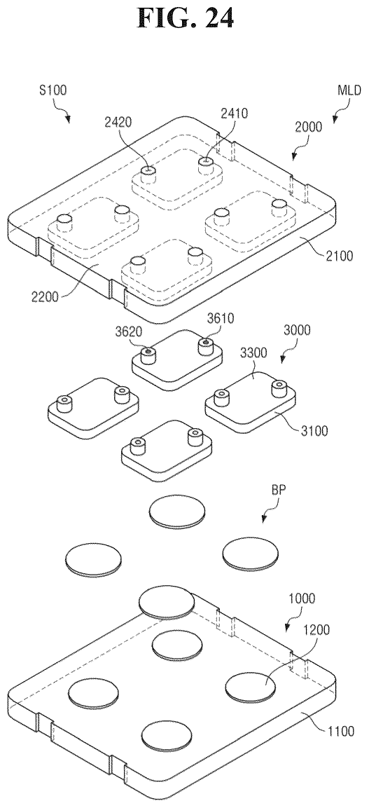

In some embodiments, the outer structure 30 may include resin. For example, the outer structure 30 may be made of an optical clear resin (OCR), but the present disclosure is not limited thereto. The outer structure 30 may be applied to the outside of the display driving module 10 in a liquid or paste state. For example, the outer structure 30 may be formed by injecting paste into a mold included in a mold unit MLD (see FIG. 24) which will be described later. Then, the outer structure 30 may be formed by curing the paste using ultraviolet rays or heat. The process of forming the outer structure 30 will be described later with reference to FIG. 23.

The coupling member 40 may be located between the cover window 20 and the middle frame 50. The coupling member 40 may bond the cover window 20 and the middle frame 50 and/or the outer structure 30 and the middle frame 50 to each other. The coupling member 40 may be an adhesive tape having an adhesive material applied to both sides and having a waterproof or dustproof function.

The coupling member 40 may be disposed along an edge of the middle frame 50. In some embodiments, the coupling member 40 may have a ring shape with a central hole in a plan view. For example, the coupling member 40 may have a donut shape or a ring shape in a plan view. In a plan view, the shape and size of the coupling member 40 may correspond to the shape and size of the middle frame 50. For example, when the middle frame 50 has a circular shape in a plan view, the coupling member 40 may also have a circular shape.

The middle frame 50 may be disposed between the cover window 20 and the bottom cover 60. The middle frame 50 may be an intermediate coupling member for coupling the cover window 20 and the bottom cover 60 together. For example, the middle frame 50 may include a bracket.

The bottom cover 60 may be disposed at the bottom of the main body unit BP. The bottom cover 60 may be disposed under the middle frame 50. The bottom cover 60 may be a housing coupled to the middle frame 50.

The bottom cover 60 may include a central cover portion 61 and a peripheral portion 62.

The central cover portion 61 may be located in the center of the bottom cover 60 and may be generally flat. The central cover portion 61 may be an area corresponding to the central portion 21 of the cover window 20. For example, the central cover portion 61 and the central portion 21 of the cover window 20 may overlap each other.

The peripheral portion 62 may be disposed around the central cover portion 61. The peripheral portion 62 may surround the central cover portion 61. The peripheral portion 62 may be a portion bent from the central cover portion 61. The peripheral portion 62 may be bent from an edge of the central cover portion 61. For example, the peripheral portion 62 may be integrally formed with the central cover portion 61. In some embodiments, a first portion of the peripheral portion 62 may include a curved surface having a predetermined curvature, and a second portion of the peripheral portion 62 may be flat. The degree (or angle) by which the peripheral portion 62 is bent from the central cover portion 61 may be an obtuse angle. However, the present disclosure is not limited thereto, and the degree (or angle) by which the peripheral portion 62 is bent from the central cover portion 61 may also be a right angle or an acute angle.

The bottom cover 60 may be disposed on an outermost rear surface of the display device 1. The bottom cover 60 may include at least one of a plastic material, a metal material and a glass material and may include a color coating layer. In an embodiment, the bottom cover 60 may be flat glass with a transparent, translucent, or opaque color coating layer.

In an embodiment, the bottom cover 60 may have the same shape as the cover window 20 and may include a glass material with a color coating layer. For example, the bottom cover 60 according to another example may be symmetrical to the cover window 20, with the middle frame 50 interposed between them, and may include a transparent, translucent, or opaque color coating layer.

The wearable portion BD may be a portion for fixing the main body unit BP to a user's wrist or the like. For example, the wearable portion BD may be any one of a strap, a chain, and a bracelet.

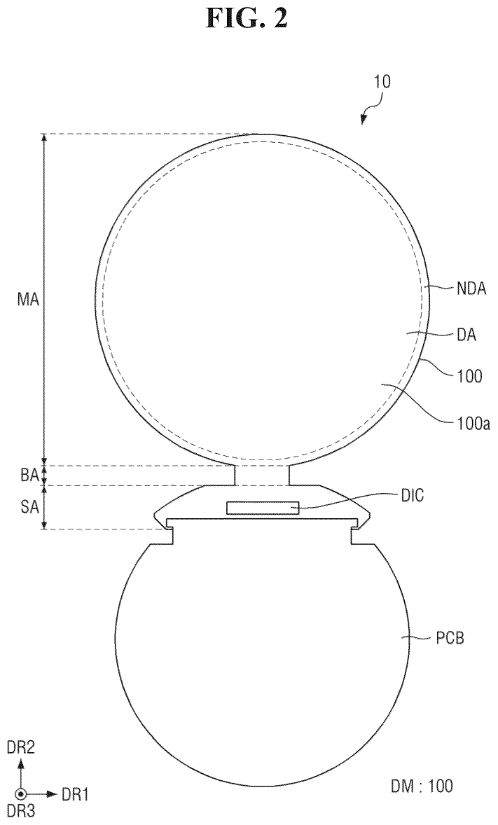

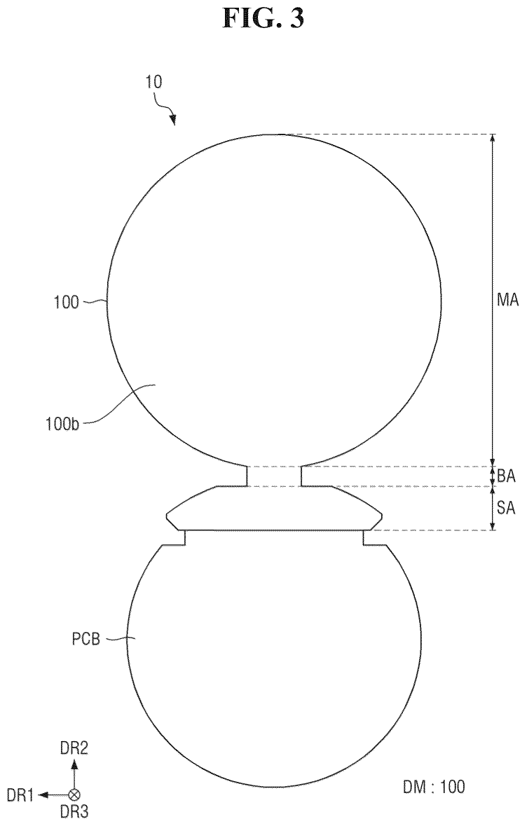

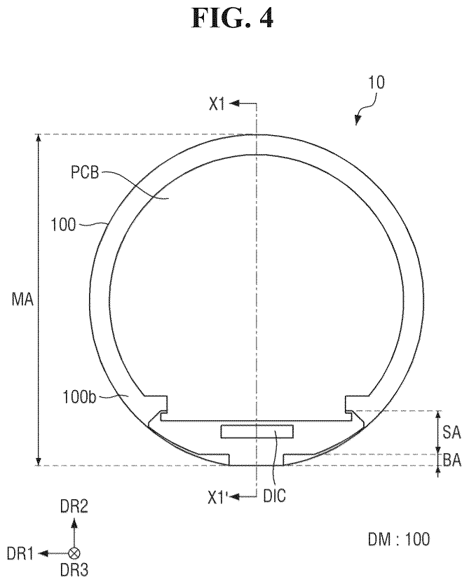

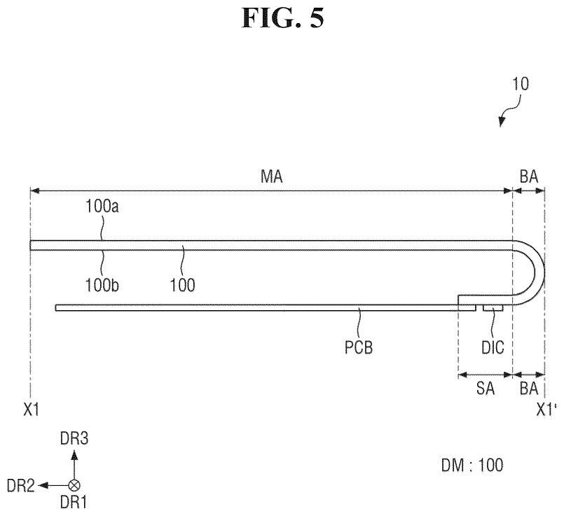

FIG. 2 is a front view illustrating an unfolded state of a display driving module 10 according to an embodiment. FIG. 3 is a rear view illustrating the unfolded state of the display driving module 10 according to the embodiment. FIG. 4 is a rear view illustrating a bent state of the display driving module 10 according to the embodiment. FIG. 5 is a schematic side view illustrating the bent state of the display driving module 10 according to the embodiment.

FIG. 2 illustrates a first surface 100a, e.g., a front surface of a display panel 100, and FIGS. 3 and 4 illustrate a second surface 100b, e.g., a back surface of the display panel 100.

Referring to FIGS. 2 through 5, the display driving module 10 may include a display module DM, a driving chip DIC, and a driving board PCB.

The display module DM may include the display panel 100. Examples of the display panel 100 may include an organic light emitting display panel, a micro light emitting diode (LED) display panel, a nano LED display panel, a quantum dot light emitting display panel, a liquid crystal display panel, a plasma display panel, a field emission display panel, an electrophoretic display panel, and an electrowetting display panel. A case in which an organic light emitting display panel is used as an example of the display panel 100 will be described below, but the present disclosure is not limited to this case, and other display panels can also be used.

The display panel 100 may include a display area DA and a non-display area NDA. The display area DA may refer to a portion of the display panel 100 that displays a screen, and the non-display area NDA may refer to a portion of the display panel 100 that does not display a screen.

The display area DA may have a circular shape in a plan view. However, the present disclosure is not limited thereto, and the display area DA may also have various shapes in a plan view, such as a rectangle or a rectangle with rounded corners, a square, other polygons, or an oval.

The non-display area NDA may be disposed around the display area DA. The non-display area NDA may be a bezel area. The non-display area NDA may surround the display area DA. However, the present disclosure is not limited thereto. For example, the non-display area NDA may not be disposed in at least a portion of the area around the display area DA.

Signal lines or driving circuits for transmitting signals to the display area DA, which may also be a touch area, may be disposed in the non-display area NDA. In an embodiment, the non-display area NDA may include a portion of the touch area, and a sensor member such as a pressure sensor may be disposed in the portion of the touch area.

The display panel 100 may include a plurality of pixels disposed in the display area DA. The pixels may be arranged in a matrix direction. Each of the pixels may be rectangular or square in a plan view. However, the present disclosure is not limited thereto, and each of the pixels may also have a rhombus shape with each side inclined with respect to a first direction DR1 or a second direction DR2. Each pixel may include an emission area. The shape of each emission area may be the same as or different from the shape of a corresponding pixel. For example, when a pixel has a rectangular shape, the emission area of the pixel may have various shapes such as a rectangle, a rhombus, a hexagon, an octagon, and a circle.

In the drawings, the first direction DR1 and the second direction DR2 are horizontal directions intersecting each other. For example, the first direction DR1 and the second direction DR2 may be orthogonal to each other. In addition, a third direction DR3 may be a vertical direction intersecting and, for example, orthogonal to the first direction DR1 and the second direction DR2. In the present specification, a direction indicated by an arrow of each of the first through third directions DR1 through DR3 may be referred to as a first side, and a direction opposite to that direction may be referred to as a second side.

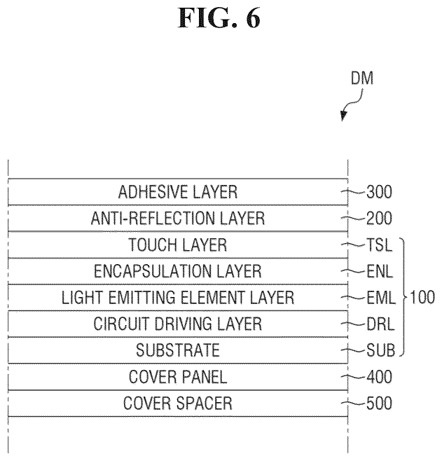

The display driving module 10 may further include a touch member that detects a touch input. The touch member may be provided on the display panel 100 in the form of a touch layer TSL (see FIG. 6). In this case, the touch layer TSL (see FIG. 6) may be provided integrally with the display panel 100. However, the present disclosure is not limited thereto, and the touch member may also be provided as a panel or film separate from the display panel 100 and attached onto the display panel 100. Although a case where the touch member is provided in the form of the touch layer TSL (see FIG. 6) is described in the following embodiments, the present disclosure is not limited thereto.

The touch area may be an area where a touch input is detected. The touch area may overlap the display area DA. For example, the display area DA may be an area where an image is displayed and a touch input is detected.

In some embodiments, the display panel 100 may include a flexible substrate including a flexible polymer material such as polyimide. Accordingly, the display panel 100 can be curved, bent, folded, or rolled.

The display panel 100 may include a main area MA, a bending area BA, and a sub-area SA. The bending area BA may be disposed between the main area MA and the sub-area SA in the second direction DR2. The main area MA may be disposed on a first side of the bending area BA in the second direction DR2. The sub-area SA may be disposed on a second side of the bending area BA in the second direction DR2.

The display area DA of the display panel 100 may be disposed within the main area MA. In an embodiment, an edge portion of the main area MA around the display area DA, the entire bending area BA, and the entire sub-area SA may be the non-display area NDA. However, the present disclosure is not limited thereto, and the bending area BA and/or the sub-area SA may also include the display area DA.

The main area MA may have a shape similar to the outer shape of the display driving module 10 in a plan view. The main area MA may be a flat area located in one plane. However, the present disclosure is not limited thereto, and at least a portion of an edge of the main area MA may be bent in the third direction DR3 to form a curved surface or may be bent in a vertical direction.

When at least a portion of the edge of the main area MA is bent in the third direction DR3 to form a curved surface or is bent in the vertical direction, the display area DA may also be disposed in the bent portion of the edge. However, the present disclosure is not limited thereto, and the curved surface or the bent portion of the edge of the main area MA may be a non-display area that does not display a screen, or a display area and a non-display area may coexist in the bent portion of the edge.

The bending area BA may be connected to a second side of the main area MA in the second direction DR2. For example, the bending area BA may be connected to a lower short side of the main area MA. A width of the bending area BA, for example, in the first direction DR1 may be smaller than a width of the main area MA adjacent to the bending area BA, for example, a width of the main area MA in the first direction DR1. A connection portion between the main area MA and the bending area BA may have an L-cut shape.

The bending area BA may be an area where the display panel 100 is bent. As illustrated in FIGS. 4 and 5, in the bending area BA, the display panel 100 may be bent downward in a thickness direction to have a curvature. For example, the display panel 100 may be bent in the bending area BA toward a second side in the third direction DR3.

The bending area BA may have a constant radius of curvature. However, the present disclosure is not limited thereto, and the bending area BA may also have a different radius of curvature in each section thereof. When the display panel 100 is bent in the bending area BA, the surface of the display panel 100 may be inverted. For example, the display panel 100 may be bent in a direction opposite to the first surface 100a which is a display surface. Accordingly, of the second surface 100b opposite the display surface, the second surface 100b of the main area MA and the second surface 100b of the sub-area SA may face each other in the third direction DR3. The sub-area SA may be disposed on the second side of the bending area BA in the second direction DR2. The sub-area SA may extend from the bending area BA. A width of the sub-area SA, for example, in the first direction DR1 may be greater than the width of the bending area BA, for example, in the first direction DR1. A connection portion between the sub-area SA and the bending area BA may have an L-cut shape.

In some embodiments, the sub-area SA may be smaller in size than the main area MA of the display panel 100. For example, as illustrated in FIG. 4, when the display panel 100 is bent, the sub-area SA may be completely overlapped by the main area MA. When the display panel 100 is bent, an outer edge of the sub-area SA may be surrounded by an outer edge of the main area MA in a plan view. The outer edge of the sub-area SA may be disposed inside the outer edge of the main area MA in a plan view.

As illustrated in FIG. 5, when the display panel 100 is bent, the sub-area SA may be overlapped by the main area MA in the thickness direction of the display panel 100, for example, in the third direction DR3. The sub-area SA may be disposed under the main area MA in the third direction DR3. In this case, a space may be formed between the sub-area SA and the main area MA in the third direction DR3.

The driving chip DIC may be disposed on the sub-area SA of the display panel 100. In some embodiments, the driving chip DIC may be disposed on the first surface 100a of the display panel 100 in the sub-area SA of the display panel 100. In an embodiment, as illustrated in the drawings, the driving chip DIC may be directly mounted on the display panel 100 using a chip on glass (COG) or chip on plastic (COP) method. In an embodiment, the driving chip DIC may be mounted on a flexible film using a chip on film (COF) method.

The driving chip DIC may generate and output data voltages, power voltages, scan timing signals, etc. The driving chip DIC may include an integrated circuit that drives the display panel 100. The integrated circuit may include an integrated circuit for a display and/or an integrated circuit for a touch unit. However, the present disclosure is not limited thereto, and the integrated circuit for a display and the integrated circuit for a touch unit may also be provided as separate chips or may be integrated into one chip.

The driving board PCB may be disposed on an end of the sub-area SA of the display panel 100. A pad unit may be disposed at the end of the sub-area SA of the display panel 100. The pad unit may include a plurality of display signal wiring pads and touch signal wiring pads. The driving board PCB may be connected to the pad unit at the end of the sub-area SA of the display panel 100. The driving board PCB may be attached to the pad unit using a conductive adhesive member such as an anisotropic conductive film or an anisotropic conductive adhesive. The driving board PCB may be a flexible printed circuit board or a flexible film such as a chip on film.

When the display panel 100 is bent, the driving chip DIC and the driving board PCB may be located opposite the main area MA with a portion of of the sub-area SA interposed between them. For example, the driving chip DIC and the driving board PCB may be disposed on the first surface 100a of the sub-area SA and, when the display panel 100 is bent, the driving chip DIC and the driving board PCB may be spaced apart from the main area MA in the third direction DR3.

In some embodiments, the driving board PCB may be smaller in size than the main area MA of the display panel 100. For example, as illustrated in FIG. 4, when the display panel 100 is bent, the driving board PCB may be completely overlapped by the main area MA of the display panel 100. When the display panel 100 is bent, an outer edge of the driving board PCB may be surrounded by the outer edge of the main area MA of the display panel 100 in a plan view. The outer edge of the driving board PCB may be disposed inside the outer edge of the main area MA of the display panel 100 in a plan view.

The planar shape of the driving board PCB may be substantially similar to the planar shape of the display panel 100. For example, when the display panel 100 is circular in a plan view, at least a portion of the driving board PCB may be circular. However, the present disclosure is not limited thereto, and the shape of the driving board PCB can be variously changed.

FIG. 6 is a schematic cross-sectional view illustrating a stacked structure of a display module DM according to an embodiment.

Referring to FIG. 6, the display module DM may include a display panel 100, an anti-reflection layer 200, an adhesive layer 300, a cover panel 400, and a cover spacer 500. The display panel 100 may include a substrate SUB, a circuit driving layer DRL, a light emitting element layer EML, an encapsulation layer ENL, and a touch layer TSL.

The substrate SUB may support components disposed thereon. The substrate SUB may include a transparent material. For example, the substrate SUB may include a transparent insulating material such as glass or quartz. The substrate SUB may be a rigid substrate. However, the present disclosure is not limited thereto, and the substrate SUB may also include plastic such as polyimide and may have flexible characteristics so that it can be curved, bent, folded, or rolled.

The circuit driving layer DRL may be disposed on a first surface, for example, an upper surface of the substrate SUB. The circuit driving layer DRL may include a circuit that drives the light emitting element layer EML of each pixel. The circuit driving layer DRL may include a plurality of thin-film transistors.

The light emitting element layer EML may be disposed on the circuit driving layer DRL. The light emitting element layer EML may include an organic light emitting layer. The light emitting element layer EML may emit light at various luminance levels according to a driving signal transmitted from the circuit driving layer DRL.

The encapsulation layer ENL may be disposed on the light emitting element layer EML. The encapsulation layer ENL may include an inorganic layer or a stacked layer of an inorganic layer and an organic layer. As another example, the encapsulation layer ENL may include glass or an encapsulation film.

The touch layer TSL may be disposed on the encapsulation layer ENL. The touch layer TSL is a layer that recognizes a touch input and may perform the function of a touch member. In other words, the touch layer TSL can function as a touch-sensitive component. The touch layer TSL may include a plurality of sensing areas and sensing electrodes.

The anti-reflection layer 200 may be disposed on the display panel 100. The anti-reflection layer 200 may reduce reflection of external light. The anti-reflection layer 200 may be attached in the form of a polarizing film. In this case, the anti-reflection layer 200 may polarize light that passes therethrough. However, the present disclosure is not limited thereto, and the anti-reflection layer 200 may also be stacked in the form of a color filter layer. In this case, the anti-reflection layer 200 may include a color filter that selectively transmits light of a specific wavelength.

The adhesive layer 300 may be disposed on the anti-reflection layer 200. The adhesive layer 300 may bond the above-described cover window 20 (see FIG. 1) to the display panel 100 or the anti-reflection layer 200. In some embodiments, the adhesive layer 300 may be an optically clear adhesive (OCA) film or a pressure sensitive adhesive (PSA) film. Although the adhesive layer 300 is included in the display module DM in FIG. 6, the present disclosure is not limited thereto. For example, the adhesive layer 300 may not be included in the display module DM, but may be attached to the cover window 20 (see FIG. 1) and provided together with the cover window 20 (see FIG. 1).

The cover panel 400 may be disposed on a second surface, for example, a lower surface of the substrate SUB. The cover panel 400 may include at least one functional layer to perform a heat dissipation function, an electromagnetic wave shielding function, a buffer function, a strength reinforcing function, a support function, and/or a bonding function. For example, the functional layer of the cover panel 400 may be a sheet layer made of a sheet, a film layer made of a film, a thin-film layer, a coating layer, a panel, or a plate. One functional layer may be composed of a single layer or may be composed of a plurality of thin layers or coating layers that are stacked. The functional layer may be, for example, a support substrate, a heat dissipation layer, an electromagnetic wave shielding layer, a shock absorption layer, or a bonding layer.

The cover spacer 500 may be disposed on the cover panel 400. The cover spacer 500 may prevent the display driving module 10 from being bent by an external force or may reduce the degree of bending of the display driving module 10. The cover spacer 500 may keep the display driving module 10 relatively flat even when an external force is applied.

The cover spacer 500 may include a rigid or semi-rigid material. For example, the cover spacer 500 may include a metal material such as stainless steel (SUS) or aluminum or include a polymer such as polymethylmethacrylate (PMMA), polycarbonate (PC), polyvinylalcohol (PVA), acrylonitirle-butadiene-styrene (ABS) or polyethylene terephthalate (PET).

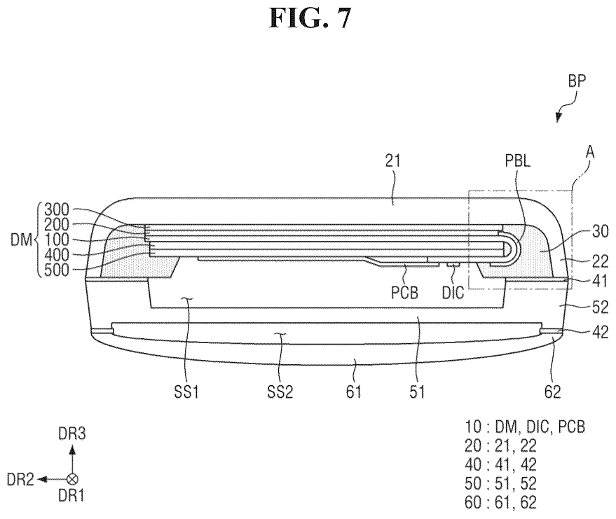

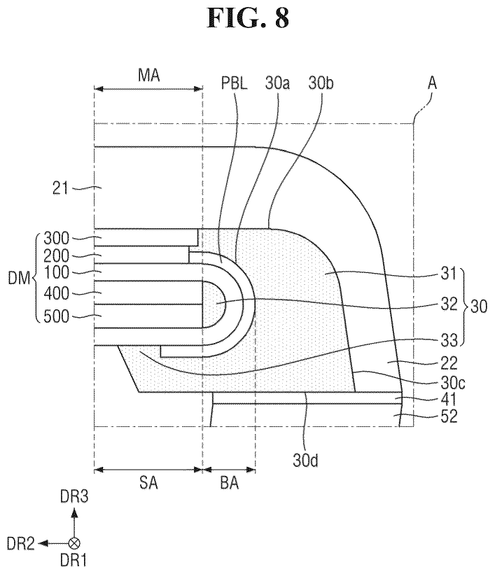

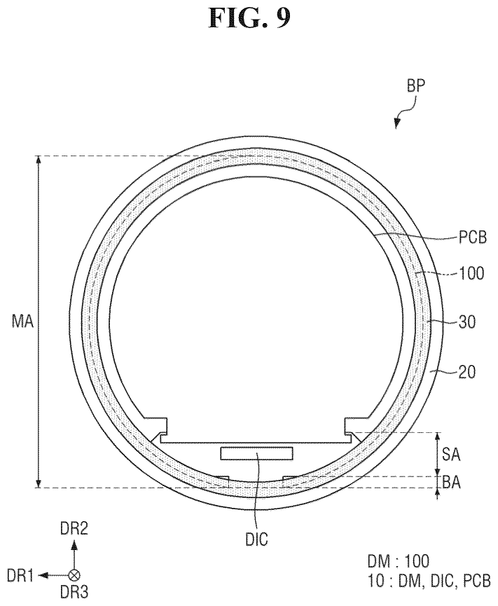

FIG. 7 is a schematic cross-sectional view of a main body unit BP according to an embodiment. FIG. 8 is an enlarged view of area A of FIG. 7. FIG. 9 is a schematic rear view of the main body unit BP according to the embodiment of FIG. 7.

Referring to FIGS. 7 through 9, the main body unit BP may include a display driving module 10, a cover window 20, an outer structure 30, a coupling member 40, a middle frame 50, and a bottom cover 60 as described above with reference to FIG. 1.

The display driving module 10 may include a display module DM, a driving chip DIC, and a driving board PCB as described above with reference to FIG. 2, etc. The display module DM may include a display panel 100, an anti-reflection layer 200, an adhesive layer 300, a cover panel 400, and a cover spacer 500 as described above with reference to FIG. 6.

The display module DM, the driving chip DIC and the driving board PCB of the display driving module 10 and the display panel 100, the anti-reflection layer 200, the adhesive layer 300, the cover panel 400 and cover spacer 500 of the display module DM have been described above, and thus, a detailed description thereof will be omitted.

The cover spacer 500 may offset a height difference between a sub-area SA of the display panel 100 and the cover panel 400 and between the driving board PCB and the cover panel 400. For example, the cover spacer 500 may be disposed between the sub-area SA of the display panel 100 and the cover panel 400 and between the driving board PCB and the cover panel 400 in the third direction DR3. Accordingly, the display panel 100 and the driving board PCB may be kept flat. In some embodiments, the sub-area SA of the display panel 100 and the driving board PCB may be attached to the bottom of the cover spacer 500 through an adhesive member. Accordingly, the sub-area SA of the display panel 100 and the driving board PCB may be kept fixed.

The display module DM may further include a bending protection layer PBL. The bending protection layer PBL may be disposed on an area of the display panel 100. In an embodiment, the bending protection layer PBL may be disposed on a bending area BA of the display panel 100. However, the present disclosure is not limited thereto, and the bending protection layer PBL may also be disposed on an area other than the bending area BA. For example, a first portion of the bending protection layer PBL may extend to the sub-area SA of the display panel 100, and a second portion of the bending protection layer PBL may extend to the main area MA of the display panel 100.

The bending protection layer PBL may be made of a polymer compound such as polyimide, acrylate, or epoxy. The bending protection layer PBL may minimize the generation of cracks due to stress applied to the display panel 100 when the display panel 100 is bent and may block the propagation of the cracks. Accordingly, the durability of the display module DM can be improved.

The cover window 20 may be attached to the display driving module 10 through the adhesive layer 300 of the display module DM. A central portion 21 of the cover window 20 may directly contact the adhesive layer 300. A curved portion 22 of the cover window 20 may surround the display driving module 10 in a horizontal direction defined by the first direction DR1 and the second direction DR2.

The outer structure 30 may be disposed between the cover window 20 and the middle frame 50 in the third direction DR3. As illustrated in FIG. 9, the outer structure 30 may surround the display driving module 10 in the horizontal direction defined by the first direction DR1 and the second direction DR2. The outer structure 30 may be surrounded by the curved portion 22 of the cover window 20 in the horizontal direction defined by the first direction DR1 and the second direction DR2.

The outer structure 30 may be disposed between the display driving module 10, the cover window 20, and the coupling member 40 (or the middle frame 50). The outer structure 30 may couple the display driving module 10, the cover window 20, and the coupling member 40 (or the middle frame 50) together.

The outer structure 30 may be disposed within a space defined by an end of the display driving module 10, an inner surface of the cover window 20, and an upper surface of the coupling member 40 (or an upper surface of the middle frame 50). For example, an inner surface 30a of the outer structure 30 may directly contact an outer edge of the display driving module 10. For example, the inner surface 30a of the outer structure 30 may directly contact a portion of the display panel 100, a portion of the adhesive layer 300 and a portion of the anti-reflection layer 200. The outer structure 30 may be disposed along the inner surface of the cover window 20. For example, an upper surface 30b of the outer structure 30 may directly contact an inner surface of the central portion 21 of the cover window 20, and an outer surface 30c of the outer structure 30 may directly contact an inner surface of the curved portion 22. The outer structure 30 may be disposed on the coupling member 40. For example, at least a portion of a lower surface 30d of the outer structure 30 may directly contact a first coupling member 41.

In the display device 1 according to the current embodiment, since the outer structure 30 is disposed on the inner surface of the cover window 20, an attachment area of the first coupling member 41 may increase, thereby improving the adhesion between the middle frame 50 and the cover window 20. Accordingly, by securing a sufficient attachment surface on the first coupling member 41 through the outer structure 30, the tolerance for coupling the cover window 20 and the middle frame 50 together can be minimized. Therefore, dead space between the cover window 20 and the display driving module 10 can be minimized. In addition, the outer structure 30 disposed between the cover window 20 and the display driving module 10 can improve the impact resistance of the display device 1.

In some embodiments, the outer structure 30 may include a first portion 31, a second portion 32, and a third portion 33.

The first portion 31 of the outer structure 30 may be disposed outside the bending area BA of the display panel 100. The first portion 31 may directly contact the inner surface of the central portion 21 of the cover window 20 and the inner surface of the curved portion 22 of the cover window 20.

The second portion 32 of the outer structure 30 may be disposed inside the bending area BA of the display panel 100. The second portion 32 may directly contact a back surface of the display panel 100, a side surface of the cover panel 400, and a side surface of the cover spacer 500 in the bending area BA of the display panel 100. In an embodiment, the second portion 32 may be formed to fill the entire space formed by the bending area BA. The second portion 32 may keep the display panel 100 bent.

The third portion 33 of the outer structure 30 may directly contact the sub-area SA of the display panel 100. The third portion 33 may cover the sub-area SA of the display panel 100. The third portion 33 may cover a back surface of the display driving module 10.

The coupling member 40 may include the first coupling member 41 and a second coupling member 42. The first coupling member 41 and the second coupling member 42 may face each other in the third direction DR3. The coupling member 40 may be an adhesive tape having an adhesive material applied to both sides and having a waterproof or dustproof function. The first coupling member 41 and the second coupling member 42 may include the same material, but the present disclosure is not limited thereto.

The first coupling member 41 may be disposed on the upper surface of the middle frame 50. The first coupling member 41 may be disposed between the middle frame 50 and the cover window 20 and between the middle frame 50 and the outer structure 30 in the third direction DR3. For example, the first coupling member 41 may couple an upper surface of a middle sidewall 52 of the middle frame 50 to a lower surface of the curved portion 22 of the cover window 20. In other words, a first portion of the first coupling member 41 may be located between the upper surface of the middle sidewall 52 of the middle frame 50 and the lower surface of the curved portion 22 of the cover window 20. In addition, the first coupling member 41 may couple the upper surface of the middle sidewall 52 of the middle frame 50 to the lower surface 30d of the outer structure 30. For example, a second portion of the first coupling member 41 may be located between the upper surface of the middle sidewall 52 of the middle frame 50 and the lower surface 30d of the outer structure 30. At least a portion (e.g., the first portion) of the first coupling member 41 may directly contact the cover window 20, and at least another portion (e.g., the second portion) of the first coupling member 41 may directly contact the outer structure 30.

The second coupling member 42 may be disposed on a lower surface of the middle frame 50. The second coupling member 42 may be disposed between the middle frame 50 and the bottom cover 60 in the third direction DR3. For example, the second coupling member 42 may couple a lower surface of the middle sidewall 52 of the middle frame 50 to an upper surface of a peripheral portion 62 of the bottom cover 60.

The middle frame 50 may serve as a bracket for fixing the cover window 20 and the bottom cover 60 to each other.

The display driving module 10 may be disposed between the middle frame 50 and the cover window 20. The upper surface of the middle frame 50 may face a lower surface of the display driving module 10. The upper surface of the middle frame 50 may be spaced apart from the lower surface of the display driving module 10. A first storage space SS1 may be formed between the upper surface of the middle frame 50 and the lower surface of the display driving module 10. The first storage space SS1 may provide a space for storing peripheral circuits of an electronic device, such as a host driving system, a memory, and a battery.

In some embodiments, the middle frame 50 may include a middle plate 51 and the middle sidewall 52.

The middle plate 51 may be disposed under the display driving module 10. In the first storage space SS1 formed between an upper surface of the middle plate 51 and the lower surface of the display driving module 10, there may be at least one opening for a cable to pass through, facilitating electrical connection between a display driving circuit unit connected to the display driving module 10 and a host driving system passes. Additionally, there may be at least one concave portion in which various electronic circuit components mounted on an electronic device are disposed.

The middle sidewall 52 may be located on a side surface of the middle plate 51. A direction in which the middle sidewall 52 extends may be different from a direction in which the middle plate 51 extends. The middle sidewall 52 may support the curved portion 22 of the cover window 20. For example, the middle sidewall 52 may be coupled to the curved portion 22 of the cover window 20 through the first coupling member 41. Accordingly, the waterproofing capability of the display device 1 can be improved, and the penetration of foreign substances can be prevented.

The bottom cover 60 may be disposed under the middle frame 50. For example, the upper surface of the bottom cover 60 may face a lower surface of the middle frame 50. At least a portion of the upper surface of the bottom cover 60 may be spaced apart from at least a portion of the lower surface of the middle frame 50. A second storage space SS2 may be formed between at least a portion of the upper surface of the bottom cover 60 and at least a portion of the lower surface of the middle frame 50. The second storage space SS2 may provide an additional space for storing peripheral circuits of an electronic device.

In some embodiments, the bottom cover 60 may include a central cover portion 61 and the peripheral portion 62.

The central cover portion 61 of the bottom cover 60 may be disposed under the middle plate 51. Peripheral circuits of an electronic device, which may not have been placed in the first storage space SS1, may be placed in the second storage space SS2 formed between an upper surface of the central cover portion 61 and a lower surface of the middle plate 51. In some embodiments, a battery for operating the display device 1 may be placed in the second storage space SS2.

The peripheral portion 62 of the bottom cover 60 may be located on a side surface of the central cover portion 61. A direction in which the peripheral portion 62 extends may be different from a direction in which the central cover portion 61 extends. The peripheral portion 62 may be supported by the middle sidewall 52. In an embodiment, the peripheral portion 62 may be coupled to the middle sidewall 52 through the second coupling member 42. Accordingly, the waterproofing capability of the display device 1 can be improved, and the penetration of foreign substances can be prevented.

In an embodiment, the bottom cover 60 may be removably coupled to the middle sidewall 52. For example, the second coupling member 42 between the middle sidewall 52 and the peripheral portion 62 may be omitted, and mechanical coupling may be adopted. In this case, a battery can be easily replaced after it discharges during the use of the display device 1. Additionally, the display device 1 can be easily disassembled for repair.

Other embodiments of the display device according to the embodiment will now be described. In the following embodiments, the same elements as those of the embodiment described above will be indicated by the same reference characters, their redundant description will be omitted or given briefly, and differences will be mainly described.

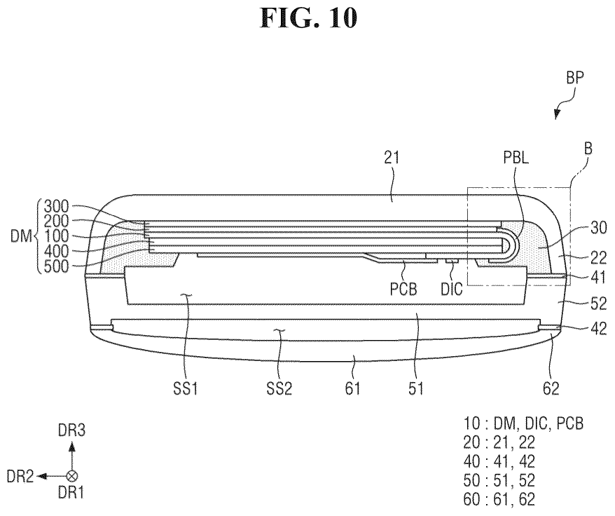

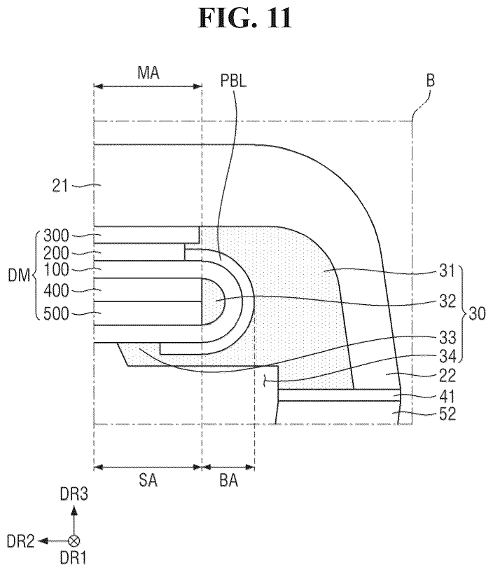

FIG. 10 is a schematic cross-sectional view of a main body unit BP according to an embodiment. FIG. 11 is an enlarged view of area B of FIG. 8.

Referring to FIGS. 10 and 11, a display device 1 according to the current embodiment is different from the display device 1 according to the embodiment described with reference to FIG. 7, in that an outer structure 30 further includes a fourth portion 34.

For example, the outer structure 30 may further include the fourth portion 34 in addition to a first portion 31, a second portion 32, and a third portion 33. Since the first portion 31, the second portion 32, and the third portion 33 have been described above with reference to FIG. 7, a detailed description thereof will be omitted.

The fourth portion 34 of the outer structure 30 may be located on the third portion 33. The fourth portion 34 may be a step portion formed on a lower surface of the outer structure 30. The lower surface of the outer structure 30 which overlaps the fourth portion 34 in the third direction DR3 may be located higher than the lower surface of the outer structure 30 which does not overlap the fourth portion 34 in the third direction DR3. The lower surface of the outer structure 30 which does not overlap the fourth portion 34 in the third direction DR3 may be in direct contact with a middle sidewall 52 of a middle frame 50.

In some embodiments, the fourth portion 34 may overlap a sub-area SA of a display panel 100 in the third direction DR3. The fourth portion 34 may extend in the first direction DR1 and the second direction DR2. Widths of the fourth portion 34 in the first direction DR1 and the second direction DR2 may be set within a range that does not lower the adhesive strength of a coupling member 40.

A first coupling member 41 may not overlap the fourth portion 34. The first coupling member 41 may contact a portion of the lower surface of the outer structure 30 other than the fourth portion 34. Accordingly, the middle sidewall 52 may be coupled to the portion of the lower surface of the outer structure 30 other than the fourth portion 34 through the first coupling member 41.

The outer structure 30 included in the display device 1 according to the current embodiment may increase an attachment area of the coupling member 40, thereby improving the adhesion between the middle frame 50 and a cover window 20. Accordingly, by ensuring a sufficient attachment surface for the first coupling member 41 through the outer structure 30, the tolerance for securely coupling the cover window 20 to the middle frame 50 can be minimized. Therefore, dead space between the cover window 20 and a display driving module 10 can be minimized. In addition, the outer structure 30 disposed between the cover window 20 and the display driving module 10 can improve the impact resistance of the display device 1.

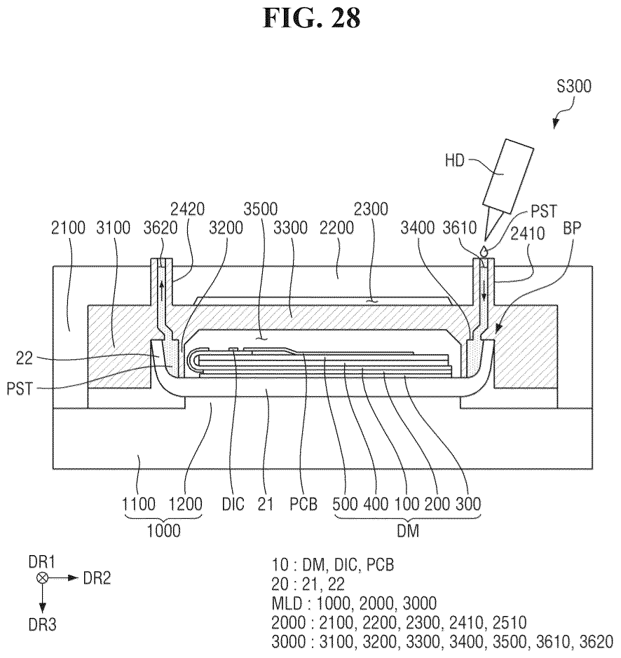

In the display device 1 according to the current embodiment, since the outer structure 30 further includes the fourth portion 34, the amount of paste PST (see FIG. 28) injected in a display device manufacturing method S1 (see FIG. 23) which will be described later can be minimized, thereby improving process efficiency.

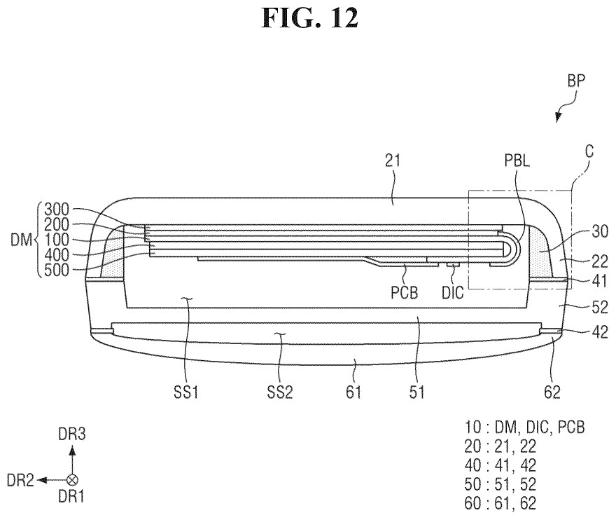

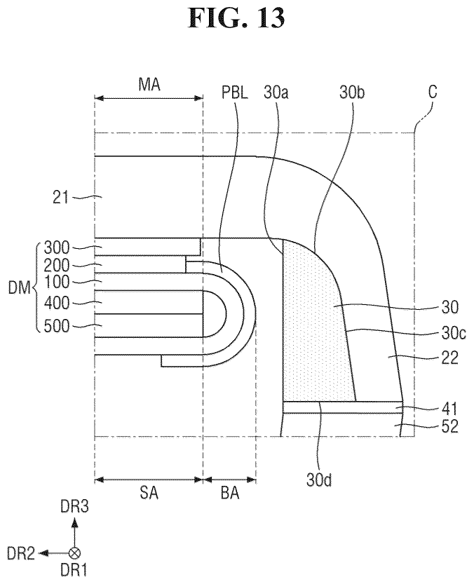

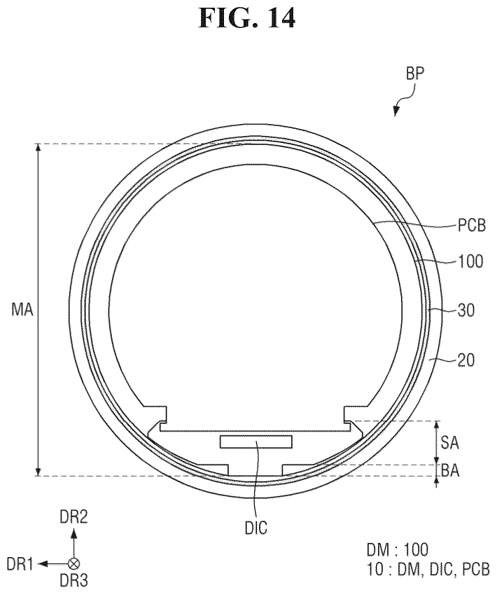

FIG. 12 is a schematic cross-sectional view of a main body unit BP according to an embodiment. FIG. 13 is an enlarged view of area C of FIG. 12. FIG. 14 is a schematic rear view of the main body unit BP according to the embodiment of FIG. 12.

Referring to FIGS. 12 through 14, a display device 1 according to the current embodiment is different from the display device 1 according to the embodiments described above with reference to FIGS. 7 and 10 in that an outer structure 30 is spaced apart from a display driving module 10.

For example, the outer structure 30 may be disposed between a cover window 20 and a middle frame 50. The outer structure 30 may couple the cover window 20 to a coupling member 40 (or the middle frame 50).

The outer structure 30 may be disposed along an edge of the display driving module 10 but may be spaced apart from the display driving module 10. For example, the outer structure 30 may be spaced apart from the display driving module 10 along the second direction DR2. The outer structure 30 may contact an inner surface of the cover window 20 and the coupling member 40 (or the middle frame 50). For example, an inner surface 30a of the outer structure 30 may be spaced apart from the display driving module 10 and may face the display driving module 10. This way, an empty space may be formed between the inner surface 30a of the outer structure 30 and the display driving module 10. An upper surface 30b and an outer surface 30c of the outer structure 30 may contact the inner surface of the cover window 20. A lower surface 30d of the outer structure 30 may contact a first coupling member 41 (or the middle frame 50).

As illustrated in FIG. 14, the outer structure 30 may have a ring shape with a central hole in a plan view. For example, the outer structure 30 may have a donut shape or a ring shape in a plan view. The outer structure 30 may surround a display panel 100 (or the display driving module 10) in a plan view but may be spaced apart from the display panel 100 (or the display driving module 10). In addition, the outer structure 30 may be surrounded by the cover window 20 in a plan view and may contact the inner surface of the cover window 20.

In the display device 1 according to the current embodiment, since the outer structure 30 is spaced apart from the display driving module 10, damage caused by the pressing of the display driving module 10 can be minimized. For example, since the outer structure 30 is spaced apart from the display driving module 10, an empty space may be located between the display driving module 10 and the inner surface 30a of the outer structure 30. Therefore, in the display device manufacturing method S1 (see FIG. 23) which will be described later, an inner wall of a mold of the mold unit MLD (see FIG. 24), which plays a sealing role, may be positioned in the empty space. Accordingly, a lower surface of the inner wall of the mold may not directly contact a lower surface of the display driving module 10 but may contact the inner surface of the cover window 20, thereby minimizing damage due to the pressing of the display driving module 10. This will be described in detail later through the display device manufacturing method S1 with reference to FIG. 23.

In addition, since the outer structure 30 is spaced apart from the display driving module 10, the amount of paste PST (see FIG. 28) injected in the display device manufacturing method S1 (see FIG. 23) which will be described later can be minimized, thus improving the process efficiency.

Furthermore, since the outer structure 30 does not cover a back surface of the display driving module 10, there is no need to perform a dotting process, which, in turn, improves the process efficiency. The dotting process refers to a process of flattening step portions located on the back surface of the display driving module 10 by applying a resin to the step portions to prevent the paste PST (see FIG. 28) from leaking from the step portions. Additionally, since a driving board PCB, a driving chip DIC, and other circuit components are disposed on the back surface of the display driving module 10, step portions may be formed between these components. When the paste PST (see FIG. 28) is applied on these step portions to form the outer structure 30, a dotting process may be performed to prevent the paste PST from leaking along the step portions. In the display device 1 according to the current embodiment, however, since the outer structure 30 does not cover the back surface of the display driving module 10, there is no need to perform the dotting process, thus improving the process efficiency.

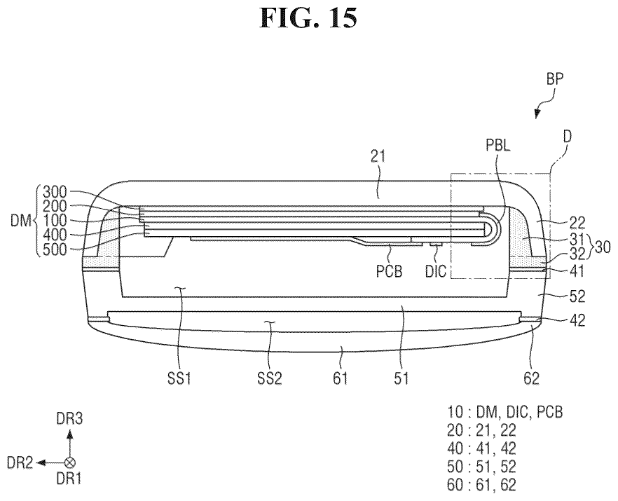

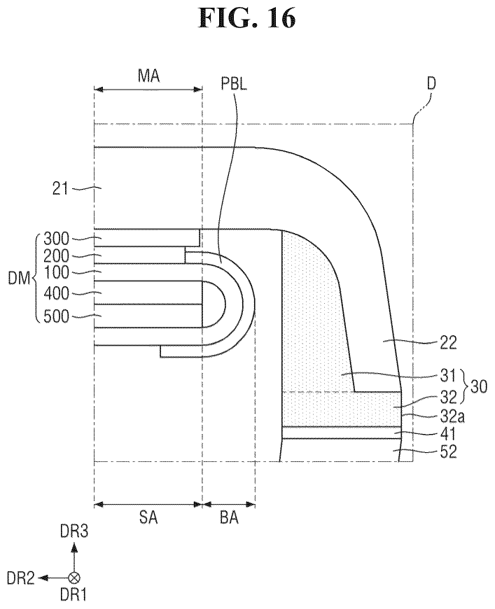

FIG. 15 is a schematic cross-sectional view of a main body unit BP according to an embodiment. FIG. 16 is an enlarged view of area D of FIG. 15.

Referring to FIGS. 15 and 16, a display device 1 according to the current embodiment is different from the display device 1 according to the embodiment described above with reference to FIG. 12 in that an outer structure 30 includes a first portion 31 and a second portion 32.

For example, the outer structure 30 may include the first portion 31 and the second portion 32.

The first portion 31 of the outer structure 30 has the same configuration as the outer structure 30 of the display device 1 according to the embodiment described with reference to FIG. 12, and thus a detailed description thereof will be omitted.

The second portion 32 of the outer structure 30 may be disposed on the first portion 31 of the outer structure 30 and a curved portion 22 of a cover window 20. For example, a first part of the second portion 32 may be disposed between a lower surface of the first portion 31 and an upper surface of a first coupling member 41 (or a middle sidewall 52). In addition, a second part of the second portion 32 may be disposed between a lower surface of the curved portion 22 and the upper surface of the first coupling member 41 (or the middle sidewall 52). This way, the curved portion 22 does not contact the upper surface of the first coupling member 41 (or the middle sidewall 52).

In some embodiments, an outer surface 32a of the second portion 32 may be located on the same line or the same plane as an outermost boundary of an outer surface of the cover window 20 in the third direction DR3. For example, the outer surface 32a of the second portion 32 may be located on the same line or the same plane as an outermost surface of the curved portion 22.

In the display device 1 according to the current embodiment, since the outer structure 30 further includes the second portion 32, an adhesive surface that a coupling member 40 (or a middle frame 50) contacts may be made of the same material at any part along the coupling member 40 (or the middle frame 50). Accordingly, the same adhesive strength can be achieved on the entire adhesive surface, thereby improving the durability of the display device 1.

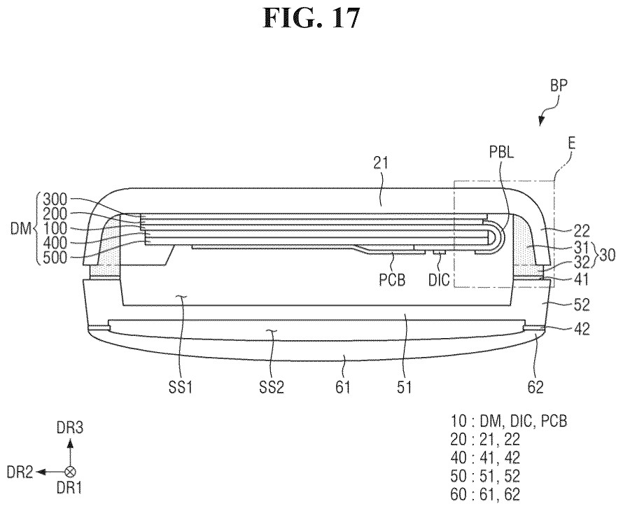

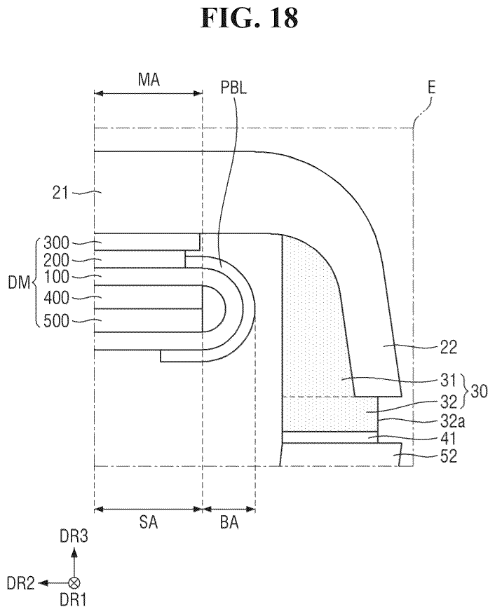

FIG. 17 is a schematic cross-sectional view of a main body unit BP according to an embodiment. FIG. 18 is an enlarged view of area E of FIG. 17.

Referring to FIGS. 17 and 18, a display device 1 according to the current embodiment is different from the display device 1 according to the embodiment described with reference to FIG. 15 in that an outer surface 32a of a second portion 32 is located inside an outer surface of a cover window 20.

More specifically, the outer surface 32a of the second portion 32 of the outer structure 30 may be located inside the outer surface of the cover window 20. For example, the outer surface 32a of the second portion 32 may be located inside an outermost surface of a curved portion 22. For example, outermost surface of the curved portion 22 may protrude further outward than the outer surface 32a of the second portion 32. In addition, an outermost surface of a middle sidewall 52 may protrude further outward than the outer surface 32a of the second portion 32.

In some embodiments, an outer surface of a first coupling member 41 may be located on the same line or the same plane as the outer surface 32a of the second portion 32 in the third direction DR3. Since the outer surface of the first coupling member 41 does not protrude further outward than the outer surface 32a of the second portion 32, it is possible to prevent external foreign substances from adhering to the first coupling member 41.

In the display device 1 according to the current embodiment, since the outer surface 32a of the second portion 32 of the outer structure 30 is located inside the outer surface of the cover window 20, the outer structure 30 can be prevented from being directly exposed to the outside.

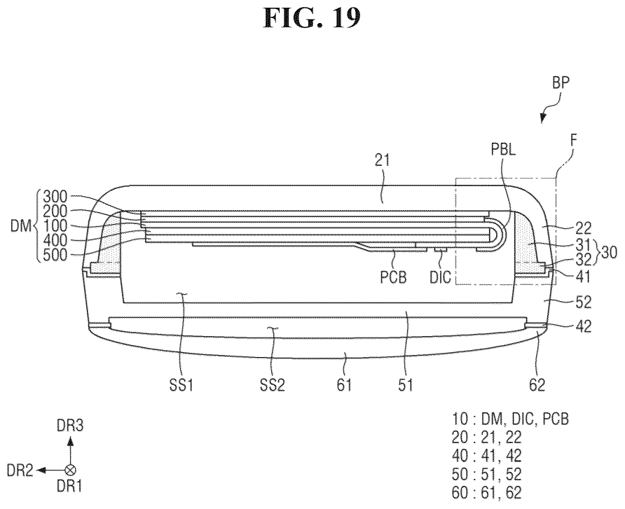

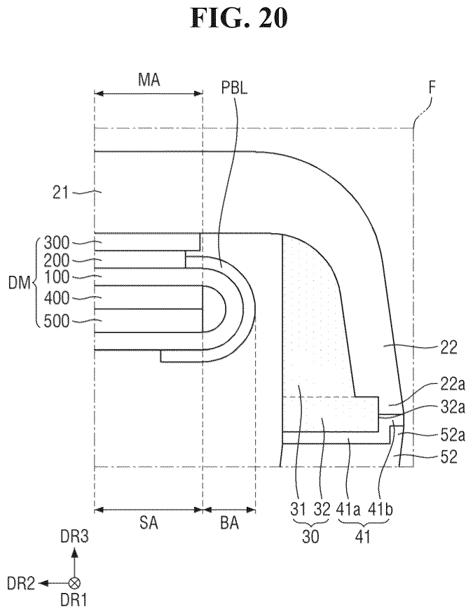

FIG. 19 is a schematic cross-sectional view of a main body unit BP according to an embodiment. FIG. 20 is an enlarged view of area F of FIG. 19.

Referring to FIGS. 19 and 20, a display device 1 according to the current embodiment is different from the display device 1 according to the embodiment described with reference to FIG. 17 in that a second portion 32 of an outer structure 30 is covered by at least any one of a curved portion 22 of a cover window 20 and a middle sidewall 52 of a middle frame 50.

For example, at least any one of the curved portion 22 of the cover window 20 and the middle sidewall 52 of the middle frame 50 may extend in the third direction DR3 to cover an outer surface of a first coupling member 41. For example, the curved portion 22 may include a first extension portion 22a, and the middle sidewall 52 may include a second extension portion 52a. The first extension portion 22a and the second extension portion 52a may cover an outer surface 32a of the second portion 32 of the outer structure 30. In an embodiment, any one of the first extension portion 22a and the second extension portion 52a may be omitted, and the other one, which is not omitted, may completely cover the outer surface 32a of the second portion 32 of the outer structure 30.

In some embodiments, the first coupling member 41 may include a first coupling portion 41a and a second coupling portion 41b. The first coupling portion 41a may be disposed between a lower surface of the second portion 32 and an upper surface of the middle sidewall 52. The second coupling portion 41b may be disposed between the first extension portion 22a and the second extension portion 52a. The outer surface of the first coupling member 41 may protrude further outward than the outer surface 32a of the second portion 32.

Although the first coupling member 41 includes a step portion extending in the third direction DR3 between the first coupling portion 41a and the second coupling portion 41b in FIGS. 19 and 20, the present disclosure is not limited thereto. For example, when the middle sidewall 52 does not include the second extension portion 52b, it may be flat without including a step portion. In this case, the first coupling member 41 may not include a step portion, and the first coupling portion 41a and the second coupling portion 41b may be disposed side by side at the same height. Here, the first extension portion 22a of the curved portion 22 may extend further in the third direction DR3 to completely cover the outer surface 32a of the second portion 32.

In the display device 1 according to the current embodiment, since the cover window 20 and the middle frame 50 having a relatively higher strength than the outer structure 30 cover the second portion 32 of the outer structure 30, the impact resistance of the display device 1 can be improved.

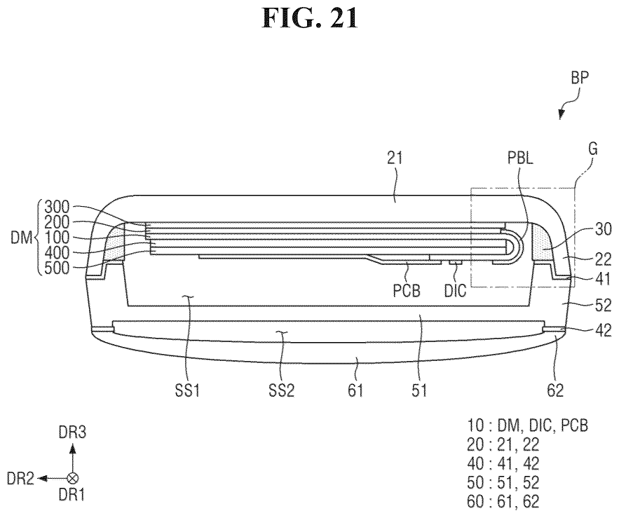

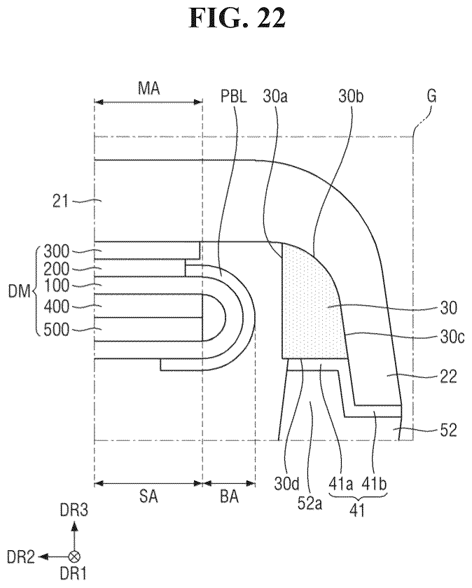

FIG. 21 is a schematic cross-sectional view of a main body unit BP according to an embodiment. FIG. 22 is an enlarged view of area G of FIG. 21.

Referring to FIGS. 21 and 22, a display device 1 according to the current embodiment is different from the display device 1 according to the embodiment described with reference to FIG. 12 in that a lower surface 30d of an outer structure 30 is located higher than a lower surface of a curved portion 22 of a cover window 20.

For example, the lower surface 30d of the outer structure 30 may be located higher than the lower surface of the curved portion 22 of the cover window 20. A first part of an inner surface of the curved portion 22 may contact the outer structure 30, and a second part of the curved portion 22 may not contact the outer structure 30.

In some embodiments, a middle sidewall 52 may include a step portion 52a. The step portion 52a may be located inside the curved portion 22. The step portion 52a may be disposed under the outer structure 30. An upper surface of the step portion 52a may be located higher than the lower surface of the curved portion 22.

A first coupling member 41 may include a first coupling portion 41a and a second coupling portion 41b. The first coupling portion 41a may be disposed between the lower surface 30d of the outer structure 30 and the step portion 52a. The second coupling portion 41b may be disposed between the lower surface of the curved portion 22 and an upper surface of the middle sidewall 52. The first coupling member 41 may further include a step portion connecting the first coupling portion 41a and the second coupling portion 41b. The step portion of the first coupling member 41 may extend in the third direction DR3.

In the display device 1 according to the current embodiment, since the lower surface 30d of the outer structure 30 is located higher than the lower surface of the curved portion 22, the amount of paste PST (see FIG. 28) injected in the display device manufacturing method S1 (see FIG. 23) which will be described later can be minimized, thereby improving the process efficiency.

In addition, since a contact area of a coupling member 40 disposed between the middle sidewall 52 and the cover window 20 is increased to improve adhesive strength, the durability of the display device 1 can be improved.

Hereinafter, an apparatus for manufacturing a display device according to an embodiment and a method of manufacturing a display device according to an embodiment will be described. For case of description, an apparatus and method for manufacturing the display device according to the embodiment described with reference to FIG. 12. will be described below as an example.

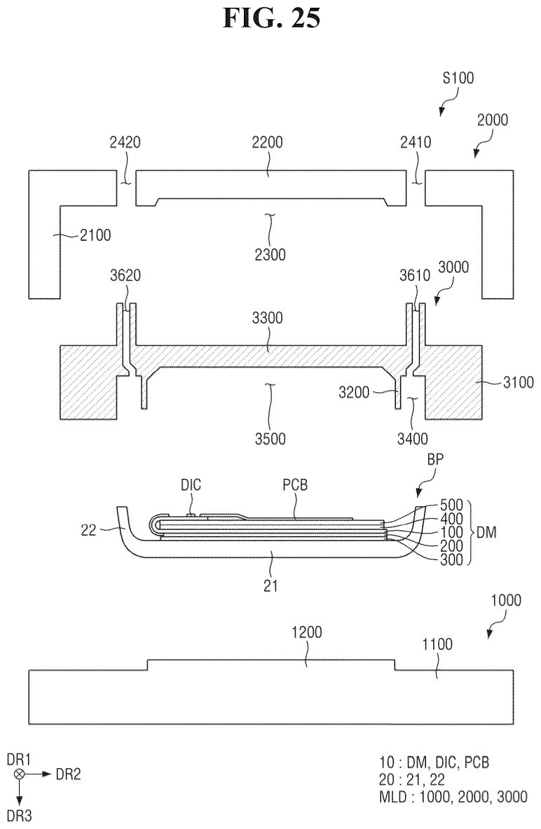

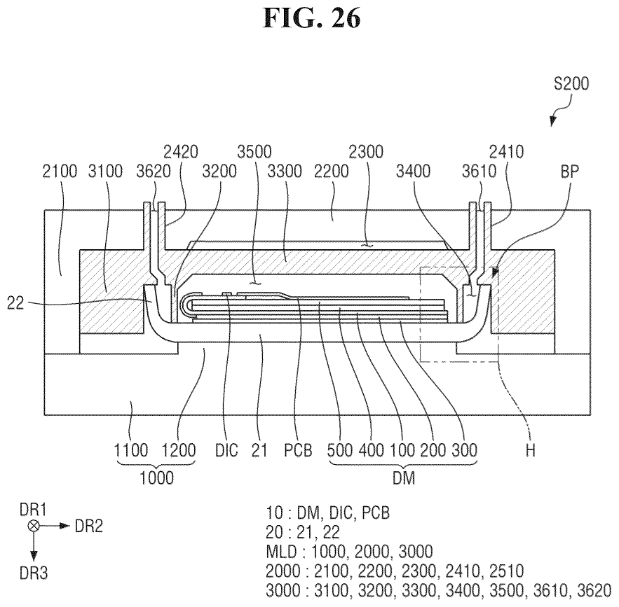

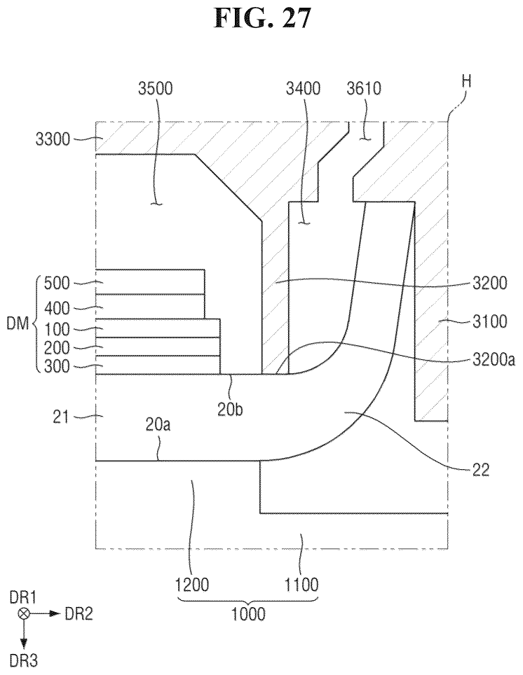

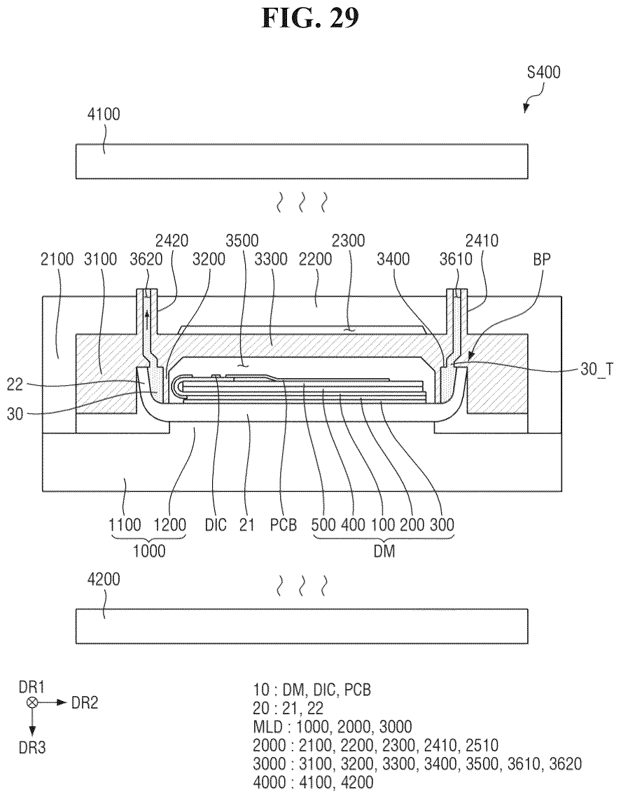

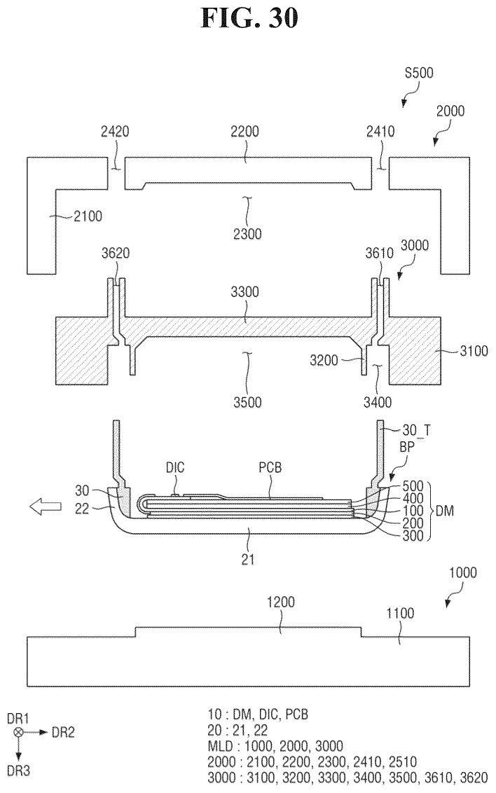

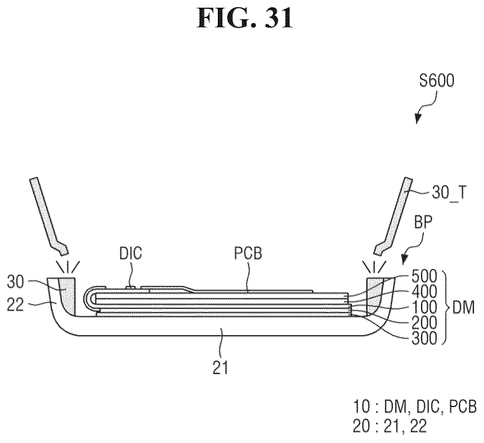

FIG. 23 is a flowchart illustrating a method of manufacturing a display device according to an embodiment. FIG. 24 is a perspective view illustrating operation S100 of FIG. 23. FIG. 25 is a cross-sectional view illustrating operation S100 of FIG. 23. FIG. 26 is a cross-sectional view illustrating operation S200 of FIG. 23. FIG. 27 is an enlarged view of area H of FIG. 26. FIG. 28 is a cross-sectional view illustrating operation S300 of FIG. 23. FIG. 29 is a cross-sectional view illustrating operation S400 of FIG. 23. FIG. 30 is a cross-sectional view illustrating operation S500 of FIG. 23. FIG. 31 is a cross-sectional view illustrating operation S600 of FIG. 23.

Referring to FIGS. 23 through 31, the method S1 of manufacturing the display device according to the embodiment may include providing a mold unit and an object (operation S100), coupling the mold unit and the object together (operation S200), injecting paste through an inlet (operation S300), forming an outer structure by curing the paste (operation S400), disassembling the mold unit and collecting the object (operation S500), and removing a tip of the object (operation S600).

As illustrated in FIGS. 24 and 25, in the providing of the mold unit and the object (operation S100), a mold unit MLD and objects may be provided.

Each of the objects may be the main body unit BP of the display device 1 described above with reference to FIG. 1, etc. The main body unit BP, which is an object in the display device manufacturing method S1 according to the current embodiment, may be in a state in which a display driving module 10 and a cover window 20 are coupled to each other.

The mold unit MLD may be a display device manufacturing apparatus for forming an outer structure 30. The mold unit MLD may include a lower mold 1000, an upper mold 2000, and inner molds 3000.

The lower mold 1000 may be disposed under the main body units BP which are the objects. The lower mold 1000 may include a base 1100 and mounting portions 1200.

The base 1100 may form the body of the lower mold 1000. The area of the base 1100 may be larger than the area of the objects. Although four objects are mounted on the base 1100 in the drawings, the present disclosure is not limited thereto. The area of the base 1100 may vary according to the number of objects mounted on the base 110.

The mounting portions 1200 may be disposed on the base 1100. The mounting portions 1200 may be portions that protrude from the base 1100 in the third direction DR3. The mounting portions 1200 and the base 1100 may be physically one component, but the present disclosure is not limited thereto. Although four mounting portions 1200 are disposed on the base 1100 in the drawings, the present disclosure is not limited thereto. The number of mounting portions 1200 disposed on the base 1100 may vary according to the number of objects mounted on the base 1100. In addition, although each of the mounting portions 1200 has the same shape and/or size as a central portion 21 of the cover window 20 in the drawings, the present disclosure is not limited thereto. Each of the mounting portions 1200 may also be larger or smaller in size than the central portion 21.

The upper mold 2000 may be disposed on the lower mold 1000. The upper mold 2000 may be disposed on the main body units BP which are the objects. The upper mold 2000 may include first outer walls 2100, a first top plate 2200, first accommodating portions 2300, first coupling holes 2410, and second coupling holes 2420.

The first outer walls 2100 and the first top plate 2200 may form the body of the upper mold 2000. The outer shape of the upper mold 2000 defined by the first outer walls 2100 and the first top plate 2200 may roughly correspond to the outer shape of the base 1100 of the lower mold 2000, but the present disclosure is not limited thereto.

Each of the first accommodating portions 2300 may be a space surrounded by the first outer walls 2100 and the first top plate 2200. Each of the first accommodating portions 2300 may provide a space for accommodating an inner mold 3000. Although four first accommodating portions 2300 are illustrated in FIG. 24 as an example, the present disclosure is not limited thereto. For case of description, a case where there is only one first accommodating portion 2300 will be described as an example in FIGS. 25 through 31 and in the following description.

The first coupling holes 2410 and the second coupling holes 2420 may be disposed in the first top plate 2200. The first coupling holes 2410 and the second coupling holes 2420 may be through holes penetrating upper and lower surfaces of the first top plate 2200. Each of the first coupling holes 2410 may be a hole to which an inlet 3610 of an inner mold 3000 is coupled, and each of the second coupling holes 2420 may be a hole to which an outlet 3620 of the inner mold 3000 is coupled.

In some embodiments, the lower mold 1000 and the upper mold 2000 may include at least any one of stainless steel (SUS) and aluminum (Al), but the present disclosure is not limited thereto.

The inner molds 3000 may be disposed between the lower mold 1000 and the upper mold 2000. The inner molds 3000, disposed between the lower mold 1000 and the upper mold 2000, serve as additional molds to more accurately seal the objects. Each of the inner molds 3000 may include second outer walls 3100, inner walls 3200, a second top plate 3300, a cavity 3400, a second accommodating portion 3500, an inlet 3610, and an outlet 3620.

The second outer walls 3100 and the second top plate 3300 may form the body of each inner mold 3000. The outer shape of each inner mold 3000 defined by the second outer walls 3100 and the second top plate 3300 may roughly correspond to the outer shape of a first accommodating portion 2300 of the upper mold 2000, but the present disclosure is not limited thereto.

The inner walls 3200 may be located inside the second outer walls 3100. The inner walls 3200 may be surrounded by the second outer walls 3100. The inner walls 3200 may be partition walls for isolating the cavity 3400 and the second accommodation portion 3500. The inner walls 3200 may extend substantially in the third direction DR3. However, the present disclosure is not limited thereto, and the inner walls 3200 may also extend in a diagonal direction.

The cavity 3400 may be located between the second outer walls 3100 and the inner walls 3200. The cavity 3400 may be a space surrounded by the second outer walls 3100, the inner walls 3200, and the second top plate 3300. The cavity 3400 may provide a space for forming the outer structure 30.

The second accommodating portion 3500 may be located inside the inner walls 3200. The second accommodating portion 3500 may be a space surrounded by the inner walls 3200 and the second top plate 3300. The second accommodating portion 3500 may be a space for accommodating the display driving module 10.

The inlet 3610 and the outlet 3620 may be disposed in the second top plate 3300. The inlet 3610 and the outlet 3620 may be passages penetrating upper and lower surfaces of the second top plate 3300. The inlet 3610 and the outlet 3620 may protrude from the second top plate 3300 in the third direction DR3. The inlet 3610 and the outlet 3620 may protrude in a direction opposite to the protruding direction of the inner walls 3200. The protruding portions of the inlet 3610 and the outlet 3620 may be respectively coupled to a first coupling hole 2410 and a second coupling hole 2420 of the upper mold 2000. For example, the protruding portions of the inlet 3610 may be inserted into the first coupling hole 2410 and the protruding portions of the outlet 3620 may be inserted into the second coupling hole 2420.

The inlet 3610 and the outlet 3620 may be spaces through which paste PST is injected. The inlet 3610 and the outlet 3620 may be passages connecting the cavity 3400 and the outside, so that the paste PST can be injected into the cavity 3400.

In some embodiments, the inner molds 3000 may include silicone, but the present disclosure is not limited thereto.

As illustrated in FIGS. 26 and 27, in the coupling of the mold unit and the object (operation S200), the upper mold 2000, an inner mold 3000, an object, and the lower mold 1000 may be arranged in order. The mold unit MLD may be assembled as the upper mold 2000, the inner mold 3000, and the lower mold 1000 are brought close to each other with the object interposed between them.

When the mold unit MLD is assembled, the object may be completely sealed by the mold unit MLD. For example, a lower surface of the cover window 20 may contact the lower mold 1000, an inner surface (upper surface) of the cover window 20 may contact lower surfaces of the inner walls 3200 of the inner mold 3000, and an upper surface of a curved portion 22 of the cover window 20 may contact an inner surface (upper surface) of the cavity 3400. For example, the curved portion 22 of the cover window 20 may be disposed in the cavity 3400, and the display driving module 10 may be disposed in the second accommodating portion 3500. Accordingly, the cavity 3400 and the second accommodating portion 3500 may be completely isolated, and the display driving module 10 may be completely sealed within the second accommodating portion 3500.

In the mold unit MLD, which is the display device manufacturing apparatus according to the current embodiment, and the display device manufacturing method S1 according to the current embodiment, since the lower surfaces of the inner walls 3200 contact the inner surface of the cover window 20, damage caused by pressing of the display driving module 10 can be minimized.

In the drawings, when the mold unit MLD is assembled, lower surfaces of the first outer walls 2100 of the upper mold 2000 contact an upper surface of the base 1100. However, the present disclosure is not limited thereto. When the mold unit MLD is assembled, the lower surfaces of the first outer walls 2100 of the upper mold 2000 may also not contact the upper surface of the base 1100.

In addition, in the drawings, when the mold unit MLD is assembled, lower surfaces of the second outer walls 3100 of the inner mold 3000 do not contact the upper surface of the base 1100 of the lower mold 1000. For example, an empty space may be formed between the lower surfaces of the second outer walls 3100 of the inner mold 3000 and the upper surface of the base 1100 of the lower mold 1000. However, the present disclosure is not limited thereto. When the mold unit MLD is assembled, the lower surfaces of the second outer walls 3100 of the inner mold 3000 may also contact the upper surface of the base 1100 of the lower mold 1000.

In addition, since the cavity 3400 does not overlap the display driving module 10, an additional dotting process is not required, thus improving the process efficiency.

As illustrated in FIG. 28, in the injecting of the paste through the inlet (operation S300), paste PST may be injected into the cavity 3400 using a head HD.

The head HD may be an injection device that can inject liquid paste PST, such as an inkjet device or a dispenser device.

The paste PST may include liquid resin. For example, the paste PST may include, but is not limited to, optically clear resin in liquid form.

The paste PST may be discharged from the head HD and injected into the cavity 3400 through the inlet 3610. Since the cavity 3400 surrounds the display driving module 10 along the inner walls 3200, the paste PST injected into the cavity 3400 may move clockwise and counterclockwise to fill the entire cavity 3400.

In some embodiments, when the cavity 3400 is filled with an amount of paste PST that exceeds the volume of the cavity 3400, the excess paste PST may be discharged through the outlet 3620. The excess paste PST may remain in the inlet 3610 and the outlet 3620.

In the mold unit MLD, which is the display device manufacturing apparatus according to the current embodiment, and the display device manufacturing method S1 according to the current embodiment, since the inner walls 3200 are disposed between the display driving module 10 and the curved portion 22 of the cover window 20, the size of the cavity 3400 may be reduced. Accordingly, the amount of paste PST injected into the cavity 3400 can be minimized, thus improving the process efficiency.

As illustrated in FIG. 29, in the forming of the outer structure by curing the paste (operation S400), the paste PST may be cured through thermal curing or ultraviolet curing to form the outer structure 30.

In some embodiments, to thermally heat the paste PST, the mold unit MLD may further include heaters 4000. For example, the heaters 4000 may include a first heater 4100 disposed above the upper mold 2000 and a second heater 4200 disposed below the lower mold 1000. However, the present disclosure is not limited thereto, and a heater surrounding the entire mold unit MLD may also be provided to apply heat from all directions. In other words, additional heater may be provided on left and right sides of the mold unit MLD.

The excess paste PST remaining in the inlet 3610 and the outlet 3620 may form tips 30_T.

As illustrated in FIG. 30, in the disassembling of the mold unit and the collecting of the object (operation S500), the lower mold 1000, the object, the inner mold 3000, and the upper mold 2000 may be decoupled and separated from each other. The object separated from the mold unit MLD may be collected to a separate room for further processing.

As illustrated in FIG. 31, in the removing of the tips of the object, the tips 30_T located on the outer structure 30 may be removed using a cutting device.

Although the tips 30_T overlap the outer structure 30 in the third direction DR3 in FIG. 30, the present disclosure is not limited thereto. In some embodiments, the tips 30_T may not overlap the outer structure 30 in the third direction DR3. In this case, the inlet 3610 and the outlet 3620 may not overlap the cavity 3400 in the third direction DR3. Accordingly, it is possible to prevent a step from being formed on a lower surface of the outer structure 30 when the tips 30_T are removed.

In concluding the detailed description, those skilled in the art will appreciate that many variations and modifications can be made to the embodiments without substantially departing from the scope of the present disclosure. Therefore, the disclosed embodiments are used in a descriptive sense and not for purposes of limitation.

What is claimed is:

1. A display device comprising:
a display driving module comprising a display panel;
a cover window comprising a central portion overlapping the display driving module and a curved portion surrounding the display driving module; and
an outer structure disposed between the display driving module and the curved portion and surrounding the display driving module,
wherein the outer structure is spaced apart from the display driving module.

2. The display device of claim 1, wherein the outer structure directly contacts the curved portion.

3. The display device of claim 1, wherein the outer structure is disposed away from an outer edge of the display driving module.

4. The display device of claim 1, wherein the outer structure does not directly contact the display driving module.

5. The display device of claim 1, wherein a lower surface of the outer structure is located on the same plane as a lower surface of the curved portion.

6. The display device of claim 1, wherein the outer structure comprises a first portion contacting an inner surface of the curved portion and a second portion overlapped by a lower surface of the first portion.

7. The display device of claim 6, wherein the second portion overlaps the first portion and the curved portion in a thickness direction of the display device.

8. The display device of claim 6, wherein the second portion contacts the lower surface of the curved portion.

9. The display device of claim 6, wherein an outermost surface of the curved portion protrudes beyond an outer surface of the second portion adjacent thereto.

10. The display device of claim 9, further comprising a middle frame located opposite the cover window with the second portion of the outer structure interposed therebetween,
wherein the outer surface of the second portion is covered by the cover window or the middle frame.

11. The display device of claim 10, further comprising a first coupling member disposed between the cover window and the middle frame, wherein
the middle frame comprises a middle sidewall facing the curved portion of the cover window, and
the first coupling member contacts a lower surface of the second portion, the lower surface of the curved portion, and an upper surface of the middle sidewall.

12. The display device of claim 11, wherein the first coupling member comprises a first coupling portion contacting the second portion, a second coupling portion contacting the curved portion, and a step portion between the first coupling portion and the second coupling portion.

13. The display device of claim 1, wherein the lower surface of the outer structure is higher than the lower surface of the curved portion.

14. The display device of claim 13, further comprising a middle frame located below the cover window,
wherein the middle frame comprises a step portion overlapping the cover window in a horizontal direction.

15. The display device of claim 14, wherein an upper surface of the step portion is higher than the lower surface of the curved portion.

16. The display device of claim 14, further comprising a first coupling member disposed between the cover window and the middle frame,
wherein the first coupling member comprises a first coupling portion disposed on the step portion and a second coupling portion disposed on the lower surface of the curved portion.

17. The display device of claim 1, wherein the display driving module further comprises a driving chip and a driving board disposed on an end of the display panel.

18. A display device comprising:
a display driving module comprising a display panel;
a cover window comprising a central portion overlapping the display driving module and a curved portion surrounding the display driving module; and
an outer structure disposed between the display driving module and the curved portion and surrounding the display driving module,
wherein the outer structure overlaps the display driving module in a thickness direction of the display panel.

19. The display device of claim 18, wherein the outer structure directly contacts the display driving module.

20. The display device of claim 18, wherein
the display panel comprises a main area, a bending area disposed on a first side of the main area and a sub-area disposed on a second side of the bending area, and
the outer structure comprises a first portion disposed outside the bending area and a second portion disposed inside the bending area.

21. The display device of claim 20, wherein the outer structure further comprises a third portion covering the sub-area of the display panel.

22. The display device of claim 21, wherein
the outer structure comprises a fourth portion disposed on a lower surface of the third portion, and
the fourth portion has a step shape.

23. An apparatus for manufacturing a display device, the apparatus comprising:
an upper mold and a lower mold facing each other; and
an inner mold located between the upper mold and the lower mold,
wherein the inner mold comprises:
outer walls;
inner walls located inside the outer walls;
a cavity disposed between the outer walls and the inner walls;
an accommodating portion disposed inside the inner walls; and
an inlet and an outlet open to the cavity.

24. The apparatus of claim 23, wherein the apparatus is configured to manufacture the display device comprising a display driving module and a cover window,
wherein lower surfaces of the inner walls are located on the cover window.

25. A method of manufacturing a display device which comprises a display driving module and a cover window, the method comprising:
coupling a mold unit and the display device together;
injecting paste through an inlet of the mold unit; and
forming an outer structure by curing the paste,
wherein the outer structure is disposed between the display driving module and the cover window.

26. The method of claim 25, further comprising removing a tip formed on the outer structure.
